(19) United States
(12) Patent Application Publication
(10) Pub. No.: US 2023/0137981 A1
(43) Pub. Date: May 4, 2023

(54) DISPLAY SCREEN AND CUTTING METHOD THEREOF

(71) Applicant: WUHAN CHINA STAR OPTOELECTRONICS SEMICONDUCTOR DISPLAY TECHNOLOGY CO., LTD., Wuhan, Hubei (CN)

(72) Inventors: Gang FANG, Wuhan, Hubei (CN); Ce CHEN, Wuhan, Hubei (CN)

(21) Appl. No.: 16/971,919

(22) PCT Filed: Jul. 22, 2020
(86) PCT No.: PCT/CN2020/103542

§ 371 Date: Aug. 21, 2020

(30) Foreign Application Priority Data
Jul. 3, 2020 (CN) 202010630767.8

(51) Int. Cl. H10K 71/00

(52) U.S. Cl. CPC H10K 71/00; H10K 50/84

(57) ABSTRACT

The present invention provides a display screen and a cutting method thereof. The display screen is provided with a protection structure along a cutting region edge, and the protection structure covers a sidewall of the cutting region edge. The protection structure is a multilayer structure, which can effectively protect edges of opening regions and slotting region of the display screen, so that force is buffered and dispersed in layers, and impact is gradually resolved, thereby improving impact resistance of the opening regions and the slotting regions of the display screen, and enhancing an entire strength of the display screen.

### FIELD OF INVENTION

The present disclosure relates to the field of display technology, and more particularly, to a display screen and a cutting method thereof.

### BACKGROUND OF INVENTION

With arrival of full-screen generation, a variety of display screen forms have developed. Until now, the most popular full-screen forms in the market include notch screens, water drop screens, digging screens, etc. Full-screen is a relatively broad definition of the mobile phone industry for a design of ultra-high screen-to-body ratio mobile phones. A literal interpretation is that an entire front of the mobile phones is a screen. Due to a limitation of current technology, the full-screen mobile phones claimed by the industry are temporarily only mobile phones with an ultra-high screen-to-body ratio. Organic light-emitting diodes (OLEDs) are a new type of display technology commonly applied in mobile phone display screens.

In order to realize a full-screen display, it is necessary to dig holes and grooves in a screen display region to reserve positions of cameras and earpieces. However, due to the digging and slotting of the display screens, it is necessary to cut the display region of the display screen. In the prior art, mechanical cutting or laser cutting is generally adopted for cutting the display screen, which is stratified cutting along an edge region of an irregular opening/ slotting shape. In the adoption of such method, there are defects as follows. Firstly, an abnormal cutting track is closer to the display region, and concentration of thermal stress causes material dispersion at an edge of the display region, resulting in sectioning or rupturing of packaging film layers, which leads to water and oxygen intrusion, causes the packaging film layers to fail, and affects display effect of the display screens. Secondly, the concentration of thermal stress caused by the stratified cutting may cause a risk of sectioning of the packaging film layers. Thirdly, after the abnormal cutting is completed, a next process is directly entered. Because there is no edge protection, it is easy to be impacted by external forces during the operation process, resulting in cracks in an abnormal cutting region.

Therefore, current technology has the defects that need to be resolved urgently.

### SUMMARY OF INVENTION

The present disclosure provides a display screen and a cutting method thereof to prevent the display screens from section of the packaging film layers caused by cutting and cracks of a cutting region caused by external forces.

In a first aspect, the present disclosure provides a display screen comprising a cutting region and a non-cutting region, and a protection structure arranged along a cutting region edge. The protection structure covers a sidewall of the cutting region edge.

In the display screen, the protection structure is a multilayer structure.

In the display screen, the protection structure comprises a buffer layer bonded to the sidewall of the cutting region edge, a reinforcing layer disposed on a side away from the cutting region edge, and a bonding layer disposed between the buffer layer and the reinforcing layer and configured to bond the buffer layer and the reinforcing layer.

In the display screen, the buffer layer is made of an elastic material.

In the display screen, a plurality of protrusions are uniformly formed on a surface of a side of the buffer layer facing the bonding layer.

In the display screen, the protrusions have curved surfaces.

In the display screen, a top of the curved surfaces is bonded to the reinforcing layer.

In the display screen, the buffer layer is made of a transparent polyurethane material.

In the display screen, the reinforcing layer is made of a metal material.

In the display screen, the bonding layer is made of a two-component adhesive.

In a second aspect, an embodiment of the present disclosure further provides a cutting method of a display screen comprising steps as follows:

Step S1: cutting and removing a portion of a center point corresponding to a cutting region by vertical cutting or angular cutting at the center point of the cutting region of the display screen.

Step S2: cutting from the center point along a spirally outward cutting path until a cutting path coincides with a cutting region edge.

Step S3: after completing the cutting, applying a protection structure along the cutting region edge of the display screen.

In the cutting method, the protection structure is a multilayer structure.

In the cutting method, the protection structure comprises a buffer layer bonded to the sidewall of the cutting region edge, a reinforcing layer disposed on a side away from the cutting region edge, and a bonding layer disposed between the buffer layer and the reinforcing layer and configured to bond the buffer layer and the reinforcing layer.

In the cutting method, the buffer layer is made of an elastic material.

In the cutting method, a plurality of protrusions are uniformly formed on a surface of a side of the buffer layer facing the bonding layer.

In the cutting method, the protrusions have curved surfaces.

In the cutting method, a top of the curved surfaces is bonded to the reinforcing layer.

In the cutting method, the buffer layer is made of a transparent polyurethane material.

In the cutting method, the cutting method uses a laser cutting method or a mechanical cutting method.

In the cutting method, the bonding layer is made of a two-component adhesive, and the reinforcing layer is made of a metal material.

Compared with the prior art, the display screen provided by the present disclosure comprises a protection structure formed on the cutting region edge, and the protection structure adopts the multilayer structure, so that force is buffered and dispersed in layers, and impact is gradually resolved, thereby improving impact resistance of opening regions and slotting regions of the display screen, and enhancing an entire strength of the display screen. The buffer layer adopts the elastic material and an arc structure, which facilitates absorption and dispersion of the force and is configured to provide a buffering effect. The reinforcing layer can enhance structural strength of the cutting region edge of the display screen, so that the force can be quickly dispersed and prevent stress concentration. In addition, the cutting method of the display screen provided by the present disclosure reduces the concentration of thermal stress generated by the cutting of the display region through a spiral grinding cutting method, thereby improving cutting yield of the edge of the sidewall of the opening regions and the slotting regions, preventing a packaging layer from stress damage, and improving display effect.

### DESCRIPTION OF DRAWINGS

FIG. 1 is a schematic structural diagram of a display screen provided by an embodiment of the present disclosure.

FIG. 2 is a schematic structural diagram of an opening edge of the display screen provided by the embodiment of the present disclosure.

FIG. 3 is a sectional structural diagram according to an A-A sectional line structure in FIG. 2.

FIG. 4 is a schematic diagram of a cutting method of the display screen provided by the embodiment of the present disclosure.

FIG. 5 is a flowchart of the cutting method of the display screen provided by the embodiment of the present disclosure.

### DETAILED DESCRIPTION OF PREFERRED EMBODIMENTS

The present disclosure provides a display screen and a cutting method thereof. In order to make a purpose, technical solutions, and effects of the present disclosure clearer, following describes the present disclosure in further detail with reference to accompanying drawings and examples. It should be understood that specific embodiments described herein are only used to explain the present disclosure, and are not used to limit the present disclosure.

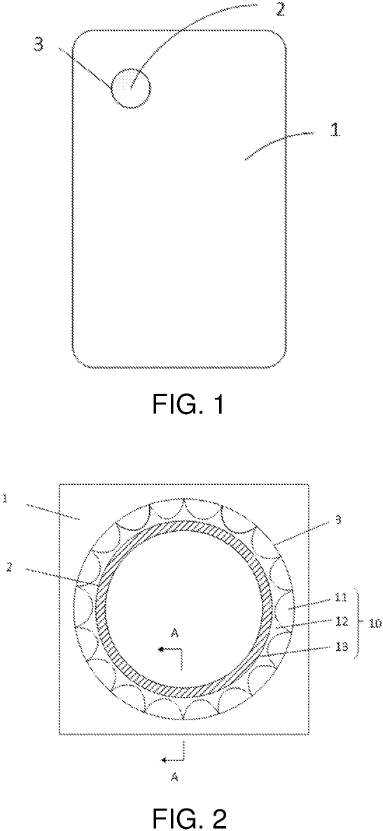

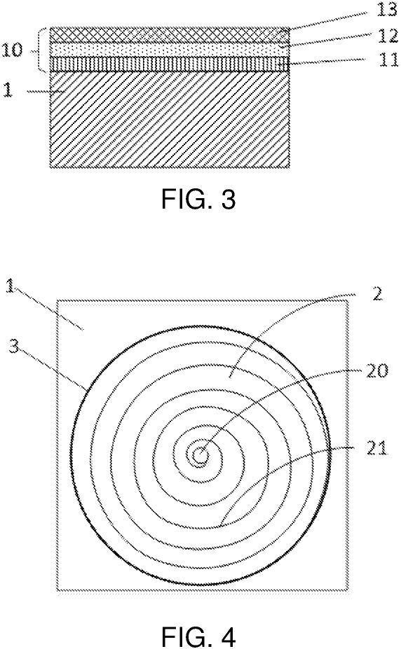

As shown in FIG. 1 to FIG. 3, a display screen 1 comprises a circular cutting region 2 and a non-cutting region around the cutting region 2, the cutting region 2 is formed with a cutting region edge 3 on the display screen 1, and a protection structure 10 is arranged along the cutting region edge and covers a side of the cutting region edge 3 of the display screen 1. The protection structure 10 uses a multilayer structure, and specifically comprises a buffer layer 11, a bonding layer 12, and a reinforcing layer 13.

The buffer layer 11 is bonded to a sidewall of the cutting region edge 3 of the display screen 1. The reinforcing layer 13 is disposed on a position away from the cutting region edge 3 of the display screen 1. The bonding layer 12 is disposed between the buffer layer 11 and the reinforcing layer 13 and is configured to bond the buffer layer 11 and the reinforcing layer 13.

In some embodiments, the buffer layer 11 is made of an elastic material such as polyurethane (PU) material. The elastic material can disperse and transmit an external force to a surrounding region through its own elastic deformation, which can effectively reduce an impact of the external force on the display screen.

In some embodiments, the reinforcing layer 13 is made of a material with certain strength and rigidity, and may be a metal material such as one or more of metals such as aluminum, magnesium, and alloys thereof, or other non-metallic materials or composite materials that meet the requirements of strength and rigidity.

In some embodiments, the bonding layer 12 is made of a material with higher viscosity, such as a two-component adhesive (AB glue). After the bonding layer is cured, in addition to being able to firmly bond the buffer layer and the reinforcing layer, its own material also has a certain degree of elasticity, which can well transmit and disperse an external impact on the cutting region edge. Therefore, the bonding layer 12 can actually function as a stress dispersion region.

Furthermore, the present disclosure creatively proposes that a plurality of uniform protrusions 14 are formed on a side of the buffer layer 11 facing the bonding layer 12.

In some embodiments, the protrusions 14 have curved surfaces, a distance between one curved surface and the reinforcing layer 13 is greater on both sides and less in a middle. When the reinforcing layer 13 is impacted by the external force, the strength and rigidity of the reinforcing layer 13 can absorb the external impact as much as possible, reduce a magnitude of deformation, and protect an internal structure. Secondly, after passing through the bonding layer, the force will first be transmitted to a top of the curved surfaces of the buffer layer 11. The top of the curved surfaces will be the first to transmit and diffuse the force to a lower part with a larger area and the bonding layer between adjacent curved regions through elastic deformation, which can effectively prevent stress concentration, resulting in a less and more uniform impact force received by the cutting region edge, thereby improving impact resistance of opening regions and slotting regions of the display screen, and enhancing an entire strength of the display screen.

In some embodiments, the top of the curved surfaces is bonded to the reinforcing layer, so that the external impact can be directly transmitted to the top of the curved surfaces of the buffer layer formed of the elastic material after the reinforcing layer 13 and then be transmitted to the surroundings, and can prevent excessive external impact from damaging a bonding state of the bonding layer between the reinforcing layer and the buffer layer, thereby causing the protection structure to be destroyed.

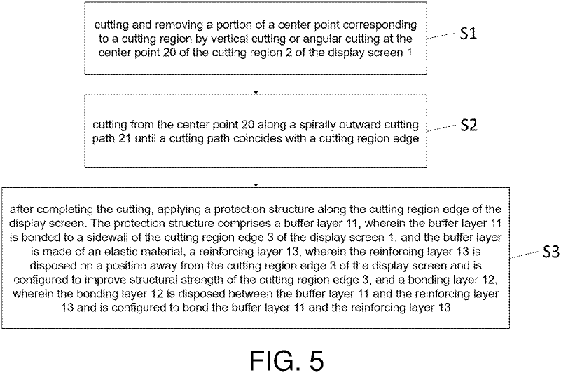

The embodiment of the present disclosure further provides a cutting method of the display screen, as shown in FIG. 4 and FIG. 5, comprising steps as follows:

Step S1: as shown in FIG. 4, cutting and removing a portion of a center point corresponding to a cutting region by vertical cutting or angular cutting at the center point 20 of the cutting region 2 of the display screen 1, so that a distance between a cutting point and a non-cutting region of the display screen can be extended, and thermal stress of high temperature of the cutting center on the non-cutting region during cutting can be reduced. For irregular opening regions or slotting regions, a geometric center or a position close to the center can be selected according to actual situations to ensure that the impact on the non-cutting region is minimized.

Step S2: cutting from the center point 20 along a spirally outward cutting path 21 until a cutting path coincides with a cutting region edge. The cutting method may use a laser cutting method or a mechanical cutting method. By cutting along the spirally outward cutting path 21, when using laser cutting or mechanical cutting, energy of a dispersive region around the cutting center is grandly cut in a spiral track, which can reduce thermal stress concentration on a cross section of the cutting region edge, and prevent the cutting region edge 3 of the cutting region 2 of the display screen 1 from material dispersion by heat and film layer fracture resulting in poor cutting.

Step S3: after completing the cutting, applying a protection structure along the cutting region edge of the display screen. The protection structure comprises a buffer layer 11, wherein the buffer layer 11 is bonded to a sidewall of the cutting region edge 3 of the display screen 1, and the buffer layer is made of an elastic material, a reinforcing layer 13, wherein the reinforcing layer 13 is disposed on a position away from the cutting region edge 3 of the display screen and is configured to improve structural strength of the cutting region edge 3, and a bonding layer 12, wherein the bonding layer 12 is disposed between the buffer layer 11 and the reinforcing layer 13 and is configured to bond the buffer layer 11 and the reinforcing layer 13. The bonding layer 12 completely occupies space between the buffer layer 11 and the reinforcing layer 13 to ensure stable adhesion and more uniform stress diffusion.

In some embodiments, the buffer layer 11 is made of a transparent polyurethane (PU) material.

Moreover, a plurality of uniform protrusions 14 are formed on a side of the buffer layer 11 facing the bonding layer 12, and the protrusions have curved surfaces. The plurality of protrusions of the present disclosure are not limited to a trajectory distribution along the cutting region edge shown in the drawings of the present disclosure. It can also be distributed along a thickness direction of the display screen 1, or can be distributed regularly or irregularly on an entire surface of the buffer layer 11 facing the bonding layer 12. The protrusions 14 can be obtained by mechanical processing or die embossing after forming the buffer layer 11.

In some embodiments, a top of the protrusions 14 is bonded to the reinforcing layer.

Moreover, in the step 3, the buffer layer 11, the bonding layer 12, and the reinforcing layer 13 in the protection structure 20 are applied in a coating process or a vapor deposition process.

The coating and vapor deposition processes are respectively applying elastic materials, adhesive materials, and hard materials to the sidewall of the cutting region edge in the coating process or the vapor deposition process to form the buffer layer 11, the bonding layer 12, and the reinforcing layer 13.

In some embodiments, the protection structure 10 of the display screen and the cutting method of the display screen of the present disclosure can also be applied to the slotting of the display screen and other abnormal cutting situations.

It is understood that for those of ordinary skill in the art, equivalent replacements or changes can be made according to technical solutions of the present disclosure and its inventive concepts, and all these changes or replacements shall fall within a protection scope of appended claims of the present disclosure.

What is claimed is:

1. A display screen, comprising a cutting region and a non-cutting region, and a protection structure arranged along a cutting region edge, wherein the protection structure covers a sidewall of the cutting region edge.

2. The display screen as claimed in claim 1, wherein the protection structure is a multilayer structure.

3. The display screen as claimed in claim 2, wherein the protection structure comprises:
a buffer layer bonded to the sidewall of the cutting region edge;
a reinforcing layer disposed on a side away from the cutting region edge; and
a bonding layer disposed between the buffer layer and the reinforcing layer and configured to bond the buffer layer and the reinforcing layer.

4. The display screen as claimed in claim 3, wherein the buffer layer is made of an elastic material.

5. The display screen as claimed in claim 3, wherein a plurality of protrusions are uniformly formed on a surface of a side of the buffer layer facing the bonding layer.

6. The display screen as claimed in claim 5, wherein the protrusions have curved surfaces.

7. The display screen as claimed in claim 6, wherein a top of the curved surfaces is bonded to the reinforcing layer.

8. The display screen as claimed in claim 4, wherein the buffer layer is made of a transparent polyurethane material.

9. The display screen as claimed in claim 3, wherein the reinforcing layer is made of a metal material.

10. The display screen as claimed in claim 3, wherein the bonding layer is made of a two-component adhesive.

11. A cutting method of a display screen, comprising steps as follows:
step S1: cutting and removing a portion of a center point corresponding to a cutting region by vertical cutting or angular cutting at the center point of the cutting region of the display screen;
step S2: cutting from the center point along a spirally outward cutting path until a cutting path coincides with a cutting region edge; and
step S3: after completing the cutting, applying a protection structure along the cutting region edge of the display screen.

12. The cutting method of the display screen as claimed in claim 11, wherein the protection structure is a multilayer structure.

13. The cutting method of the display screen as claimed in claim 12, wherein the protection structure comprises:
a buffer layer bonded to a sidewall of the cutting region edge;
a reinforcing layer disposed on a side away from the cutting region edge; and
a bonding layer disposed between the buffer layer and the reinforcing layer and configured to bond the buffer layer and the reinforcing layer.

14. The cutting method of the display screen as claimed in claim 13, wherein the buffer layer is made of an elastic material.

15. The cutting method of the display screen as claimed in claim 13, wherein a plurality of protrusions are uniformly formed on a surface of a side of the buffer layer facing the bonding layer.

16. The cutting method of the display screen as claimed in claim 15, wherein the protrusions have curved surfaces.

17. The cutting method of the display screen as claimed in claim 16, wherein a top of the curved surfaces is bonded to the reinforcing layer.

18. The cutting method of the display screen as claimed in claim 14, wherein the buffer layer is made of a transparent polyurethane material.

19. The cutting method of the display screen as claimed in claim 11, wherein the cutting method uses a laser cutting method or a mechanical cutting method.

20. The cutting method of the display screen as claimed in claim 13, wherein the bonding layer is made of a two-component adhesive, and the reinforcing layer is made of a metal material.
